(19) United States
(12) Patent Application Publication
(10) Pub. No.: US 2025/0095154 A1
(43) Pub. Date: Mar. 20, 2025

(54) METHOD AND SYSTEM FOR CHARACTERIZING A SPATIAL PATTERN FOR A MICROSTRUCTURAL PROPERTY OF A BIOLOGICAL TISSUE

(71) Applicants: Siemens Healthineers AG, Forchheim (DE); Centre Hospitalier Universitaire Vaudois, Lausanne (CH)

(72) Inventors: Tobias Kober, St-Sulpice (CH); Veronica Ravano, Ecublens (CH); Stefan Sommer, Zürich (CH)

(21) Appl. No.: 18/889,640

(22) Filed: Sep. 19, 2024

(30) Foreign Application Priority Data
Sep. 19, 2023 (EP) 23198152.3

(51) Int. Cl. G06T 7/00; G01R 33/48; G01R 33/56; G06T 7/73; G06V 10/764

(52) U.S. Cl. CPC G06T 7/0014; G01R 33/4828; G01R 33/5608; G06T 7/74; G06V 10/764; G06T 2207/10088; G06T 2207/30016

(57) ABSTRACT

A system and a method for characterizing a spatial distribution of a tissue microstructural property from quantitative imaging data. A property map for a tissue of a biological object is acquired. An intensity of voxels of the property map represents a measured value V of the microstructural property. A distance d is determined for each of a set of voxels from a center of interest, to associate each voxel to a measured value V and a determined distance d. A function f is fitted for the voxels with a set of fitting parameters and the values of each fitting parameter is determined from the fit. Then, the value of at least one of the fitting parameters is output.

### CROSS-REFERENCE TO RELATED APPLICATION

This application claims the priority, under 35 U.S.C. § 119, of European Patent Application EP 23198152.3, filed Sep. 19, 2023; the prior application is herewith incorporated by reference in its entirety.

### FIELD AND BACKGROUND OF THE INVENTION

The present disclosure is directed, in general, to imaging techniques for imaging biological objects, such as tissue, using for instance magnetic resonance imaging (MRI). More specifically, the present invention is directed to methods and systems for characterizing microstructural properties of biological tissue from a property map, e.g., from a spatial map of quantitative MRI (qMRI) parameters.

In most radiologically-diagnosed diseases (e.g., tumor, multiple sclerosis, Alzheimer's disease), radiologists identify an anatomical anomaly and monitor its evolution over time to establish the patient's diagnosis, prognosis and/or treatment planning. For instance, in multiple sclerosis, demyelinating lesions are typically detected in the brain using conventional MRI sequences. The progression of the disease is then evaluated by considering, among others, the evolution of brain lesions over time in terms of the number of lesions and volume change. The pathophysiological mechanisms that are at the source of the progression of an anomaly (e.g., the accumulation of macrophages at the lesion border in multiple sclerosis) are often theoretically understood, yet not quantifiable using conventional clinical imaging techniques. It would be clinically relevant, however, to characterize microstructural properties of normal-appearing tissue as it could be predictive of future progression (e.g., lesion enlargement for multiple sclerosis, hippocampus atrophy in Alzheimer's disease).

In this context, property mapping techniques such as qMRI have been shown to be of interest to quantify tissue microstructural change in response to pathology, and to bring valuable complementary information to standard radiological metrics [1, 2]. In fact, property mapping like qMRI techniques allow to study microstructural tissue composition, both in abnormal and normal-appearing tissue. For instance, previous work has shown the relevance of estimating microstructural properties of normal-appearing tissue in multiple sclerosis [3]. In particular, a gradient of increasing alterations was found in periventricular normal-appearing tissue and showed to correlate with disability [4]. Other studies focused on the estimation of normal-appearing tissue surrounding multiple sclerosis lesions (so-called perilesional tissue) [5,6]. These findings suggest that estimating the relation between tissue microstructural properties and their location in space is of relevance to characterize a disease. However, to this date, solutions that are able to efficiently and precisely characterize such relation are still missing.

Indeed, existing solutions aim at characterizing microstructural alterations in normal-appearing tissue surrounding an area of interest by implementing a “ring-based approach”. For instance, Vaneckova et al. [4] proposed to compute a Euclidean distance map, where each voxel of a brain image is associated with an intensity representing the distance to the border of the brain ventricles. Periventricular bands were then extracted by applying distance thresholds and discretizing the distance map. And finally, average qMRI values were estimated in each periventricular band and a gradient was observed by comparing values between different bands. Similar solutions were proposed in the papers of Shi et al. [5] and Wittayer et al. [6].

One problem of the proposed solutions is a lack of sensitivity that decreases the information that can be extracted from the obtained results. Another disadvantage of existing techniques is that the information on spatial distribution of the tissue properties is not well condensed in an easily usable, ideally a scalar, value. This can be crucial for the clinical adoption of such a metric.

### SUMMARY OF THE INVENTION

It is an objective of the present invention to disclose a method and a system that are capable of precisely and efficiently characterizing the relation between a tissue microstructural property and its location in space with respect to a center of interest, notably in order to provide results based on quantitative metrics, e.g. qMRI metrics, that enable comparison between patients independently from an examination site or MRI apparatuses used for acquiring images of the patients.

With the above and other objects in view there is provided, in accordance with the invention, a method and a system for characterizing a tissue microstructural property as a function of its location with respect to a center of interest. There is provided a computer-implemented method for characterizing a spatial distribution of a tissue microstructural property from quantitative imaging data, the method comprising
acquiring, for a biological object and via a first interface, a property map for a tissue of the biological object, wherein the property map comprises voxels whose intensity represents a measured value V of the microstructural property for the tissue;
determining, for at least a set of the voxels, a distance d separating each voxel of the set from a center of interest so that each voxel of the set is associated with a measured value V and a determined distance d;
fitting, for the set of voxels, a function f to the measured values V expressed as a function of the determined distance d according to V(d)=f(β₁, . . . , β_{N},d) in order to determine a set of fitting parameters; determining, from the fit, values of each fitting parameter; and outputting a value of at least one of the fitting parameters.

More specifically and in other words, the computer-implemented method for characterizing a spatial distribution of a tissue microstructural property from quantitative imaging data, such as qMRI data, comprises:
receiving or acquiring, for a biological object and via a first interface, a property map, e.g. a qMRI map, for a tissue of said biological object, e.g. a brain, wherein said property map comprises voxels whose intensity represents a measured value V, notably a measurable quantitative value, of said microstructural property for said tissue, said microstructural property being for instance defined as a measurable quantitative parameter. In particular, said property map is a quantitative T1 or a quantitative T2 map of a brain, wherein, in this case, the measured or mapped brain tissue quantitative parameter or property is then the T1 or T2 relaxation time measured for instance in milliseconds. Said property map might be derived from another property map, for instance it can be a deviation map showing differences of measured quantitative values with respect to normative values (e.g., a z-scope map). Said property map might also be a combination of a T1 and T2 map, or a map of an electrical parameter/property of said tissue (e.g. tissue conductivity), or a map of magnetization transfer characteristics of a tissue (e.g. magnetization transfer ratio (MTR), fractional pool-size, exchange rates measured for a brain), or any other voxel-wise quantifiable property related to a tissue. Preferentially, the property map is acquired by qMRI. Optionally, it is acquired by qMRI combined with one or several other imaging techniques (e.g. computed tomography (CT) or ultrasound imaging technique) capable of quantifying a tissue microstructural property. Said property map might also be a CT image of said biological object configured for providing a map of said tissue microstructural property or parameter. In particular, said property map might be obtained by combining quantitative measurements of different tissue microstructural properties, i.e. by combining different quantitative parameters measured for a same voxel of the tissue. In particular, said property map might be a 2-dimension (2D) or 3-dimension (3D) map. Preferentially, said property map is a quantitative map;
determining, for at least a set of said voxels, a distance d, e.g. an Euclidean distance, separating each voxel (i.e. its position) of said set from a center of interest (i.e. from the position of a center of interest, wherein said center of interest can be for instance a closest lesion boundary with respect to the considered voxel, or a center of a lesion, etc.) so that each voxel of said set be associated to a measured value V and a determined distance d.

In further detail, the novel method is characterized as follows:
fitting, for said set of voxels, a function f to the measured values V expressed in function of the determined distance d in order to determine a set of fitting parameters (β₁, . . . , β_{N}) with N a positive integer, N≥1, preferentially N=2, i.e. solving

$$V ( d ) = f ( {β}_{1} , … , {β}_{N} , d ) \qquad Eq . 1$$

wherein V(d) is the measured value V associated to a voxel located at the determined distance d of said center of interest and f is a function of the parameters (β₁, . . . , β_{N},d), the fitting parameters (β₁, . . . , β_{N}) being therefore unknown parameters whose value, obtained after said fit, characterizes a spatial distribution of the measured values V;
determining or extracting, from said fit, the values of each fitting parameter (β₁, . . . , β_{N});
outputting, via a second interface, the value of at least one of said fitting parameters (β₁, . . . , βN).

With the above and other objects in view there is also provided, in accordance with the invention, a system for characterizing a spatial distribution of a tissue microstructural property from quantitative imaging data, said system comprising:
a first interface for receiving or acquiring a property map, e.g., a qMRI map, for a tissue of a biological object, wherein said property map comprises voxels whose intensity represents a measured value V of said microstructural property for said tissue;
a memory for storing said property map;
a control unit with a processor, the control unit being configured for
   determining, for at least a set of said voxels, a distance d, e.g., a Euclidean distance, separating each voxel of said set from a center of interest so that each voxel of said set be associated to a measured value V and a determined distance d;
   for said set of voxels, fitting a function f(β₁, . . . , β_{N},d) to the measured values V along the determined distance d according to V(d)=f (β₁, . . . , β_{N},d), wherein V(d) is the measured value V associated to a voxel of said set located at the determined distance d of said center of interest, and (β₁, . . . , β_{N}) are fitting parameters;
   extracting, from said fit, the values of each fitting parameter (β₁, . . . , β_{N});
a second interface, connected to the control unit, and configured for outputting the value of at least one of said fitting parameters (β₁, . . . , β_{N}). Said second interface might be the same as the first interface, and may comprise for instance a display connected to the control unit and configured for displaying the values of the fitting parameters (β₁, . . . , β_{N}).

The present invention further concerns an imaging apparatus, e.g., an MRI apparatus, comprising the previously described system, wherein said imaging apparatus is typically configured for acquiring said property map or deriving it from existing sequences (i.e., z-score maps).

In accordance with a preferred embodiment of the invention, the method comprises, and the control unit is configured for, comparing the value obtained for at least one of said fitting parameter, e.g. said outputted value, to a reference value. In particular, if a difference between said value, notably the outputted value, and the reference value is greater than a predefined threshold, then the method comprises automatically sending a warning signal. In other words, said comparison might be used for triggering an automatic sending of said warning signal.

Optionally, said method comprises, and the control unit is configured for, automatically classifying the tissue in a class of tissue in function of the value of at least one of said fitting parameters, e.g. in function of the outputted value.

Preferably, if said microstructural property of the tissue is anisotropic, i.e. varies in the space in function of the location of the voxel, then the function f may further depend on different anisotropic directions within the tissue, and thus on the position of the voxel in addition to said distance d. For instance, the above Eq. 1 could be expressed as

$$V ( \vec{r} , d ) = f ( {β}_{1} , … , {β}_{N} , \vec{r} , d ) \qquad Eq . 2$$

wherein \vec{r} represents the position (e.g. the coordinates) of the voxel within a frame of reference, d is the determined distance between the position of said voxel and said center of interest, i.e. the position of said center of interest within said frame of reference.

In particular, said set of voxels might be obtained by applying a mask to the property map in order to select, by means of said mask, voxels belonging to a specific region of said biological object and which form said set. Such a mask configured for defining or selecting a specific region within a biological object as well as the technique used for applying such a mask to a map are known in the art and therefore do not need to be further described here. Alternatively, said set of voxels might be obtained by clustering the voxels of the property map, using for instance k-means clustering techniques.

The foregoing has broadly outlined the features and technical advantages of the present disclosure so that those skilled in the art may better understand the detailed description that follows. Additional features and advantages of the disclosure will be described hereinafter that form the object of the claims. Those skilled in the art will appreciate that they may readily use the concept and the specific embodiment disclosed as a basis for modifying or designing other structures for carrying out the same purposes of the present disclosure. Those skilled in the art will also realize that such equivalent constructions do not depart from the spirit and scope of the disclosure as defined by the set of claims.

Other features which are considered as characteristic for the invention are set forth in the appended claims.

Although the invention is illustrated and described herein as being embodied in a method and a system for characterizing a spatial pattern for a microstructural property of a biological tissue, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE FIGURES

FIG. 1 illustrates a flowchart of a method for characterizing a spatial distribution of a microstructural property of a tissue from qMRI data according to the invention;

FIG. 2 illustrates a preferred embodiment of a system for characterizing a spatial distribution of a microstructural property of a tissue from qMRI data according to the invention;

FIG. 3 schematically represents a lesion surrounded by normal-appearing tissue;

FIG. 4 presents a graph of measured values V for T1 relaxation time in function of the distance d obtained for the lesion of FIG. 3 and fitted by a preferred function f according to the invention;

FIGS. 5 and 6 present experimental results when applying the method according to the invention;

FIG. 7 presents a schematic comparison of the fitting results for a same type of tissue.

### DETAILED DESCRIPTION OF THE INVENTION

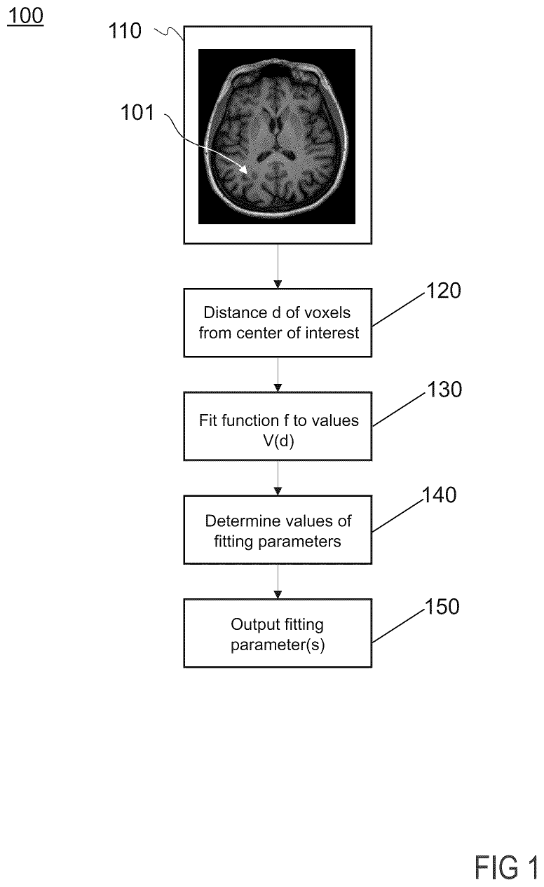

The details of FIGS. 1 to 7, described below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged device. The numerous innovative teachings of the present application will be described with reference to exemplary non-limiting embodiments.

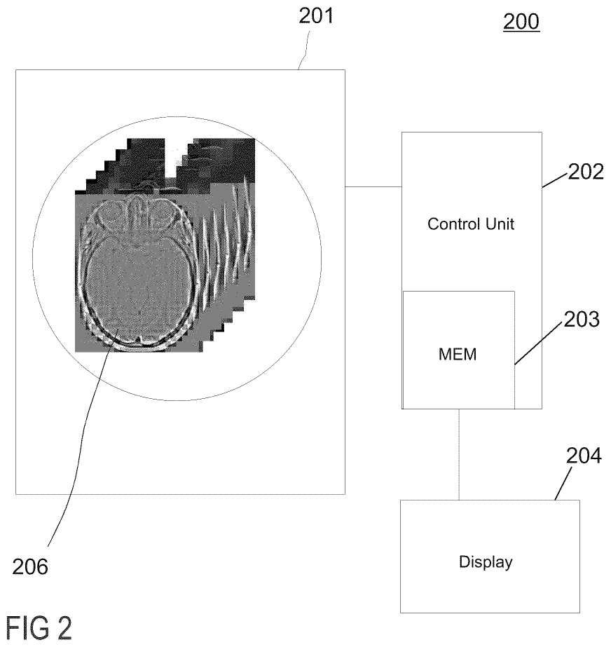

Referring now to the figures of the drawing in detail and first, in particular, to FIGS. 1 and 2 thereof, there are shown details of the method according to the invention, with FIG. 1 describing the different steps of the method 100 carried out by a preferred embodiment of the system 200 according to the invention which is illustrated by FIG. 2.

In FIG. 2, a control unit 202 of the system 200 according to the invention is preferably connected, for instance via a first interface, to an imaging apparatus, as it is known in the art, e.g., an MRI apparatus 201. While qMRI will be taken as concrete illustration of the present invention, other imaging apparatus might be connected to the system 200 according to the invention, as long as it can provide the system 200 with a property or quantitative map of a tissue microstructural property for a tissue of a biological object 206.

The MRI apparatus 201 typically comprises different coils and respective coil controllers configured for generating magnetic fields and RF pulses in order to acquire an MRI signal from the biological object 206, e.g. a brain, under investigation. Said MRI signal is transmitted by a receiver coil controller to the control unit 202. The latter might be configured for reconstructing qMRI maps of the biological object 206 from said MRI signal. In particular, the control unit 202 might be configured for controlling the MRI apparatus 201 so that the latter performs MR imaging enabling an acquisition of qMRI maps. Alternatively or additionally, the control unit 202 might be connected to a database or any other system for acquiring or receiving, e.g. via said first interface, a property map, e.g. a qMRI map, of the tissue microstructural property of said biological object. Said control unit 202 comprises typically a memory 203 and is connected to a second interface, e.g. a display 204 for displaying images reconstructed from the received MRI signal. The system 200 according to the invention might also be part of the MRI apparatus 201.

According to the present invention, the system 200 is configured for carrying out the following steps:

At step 110, the system 200, e.g. its control unit 202, receives or acquires one or several property maps configured for mapping a microstructural property of a tissue of the biological object 206. Said property maps are for instance qMRI maps 101 obtained from MRI scans of a brain with techniques as they are known in the art for providing quantitative MRI data. Said property map might by any map derived from a qMRI map, such as, for example, a z-score map.

According to the present invention, the property map is a biological object map made of voxels, wherein the intensity value of each voxel is a measure of a tissue parameter (or property) obtained, for said biological object 206, via a quantitative imaging technique, preferably a qMRI technique. In particular, a qMRI map according to the invention may be, for instance:
T1 map, measuring T1 relaxation time;
T2 map, measuring T2 relaxation time;
T2* map, measuring T2* relaxation time;
T1r map, measuring T1r relaxation time;
MT (magnetization transfer), measuring tissue myelination;
any diffusivity map, such as tissue fractional anisotropy;
myelin water imaging, measuring tissue myelination;
quantitative conductivity map, measuring tissue electrical conductivity;
quantitative susceptibility map, measuring tissue magnetic susceptibility;
quantitative elastography map, measuring tissue mechanical stiffness.

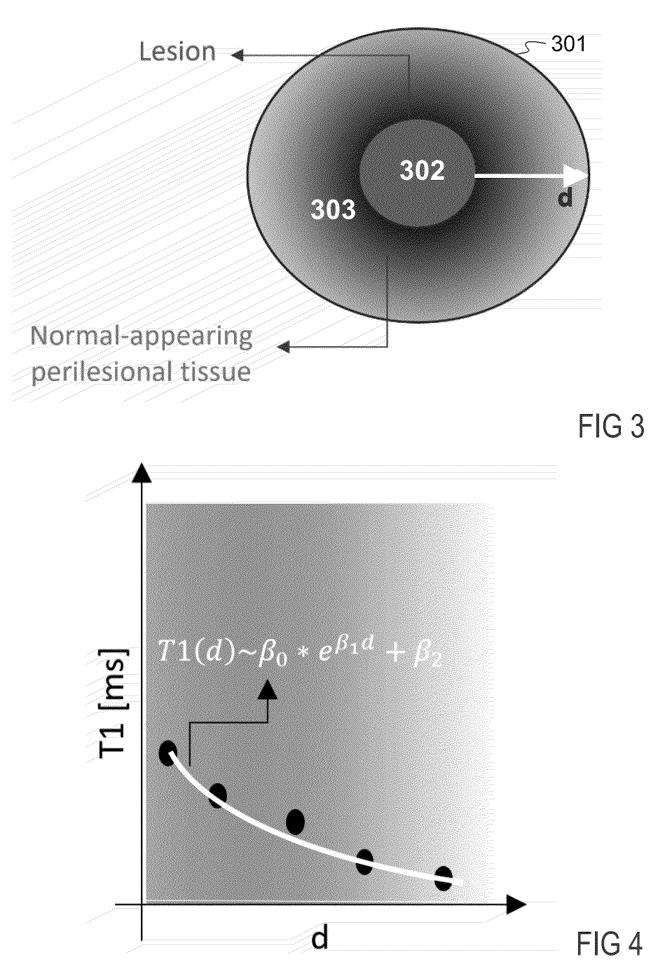

FIG. 3 schematically represents an acquired property map 301 for a tissue of a biological object. As shown in FIG. 3, the acquired property map 301 may cover a region of the biological object 206 that comprises a lesion 302 surrounded by normal-appearing perilesional tissue 303. The present invention enables notably to characterize a microstructural property of said perilesional tissue 303.

At step 120, the system 200, e.g., its control unit 202, determines or measures, for each voxel of a set of voxels within said property map, a distance d, which is preferentially a Euclidean distance, separating the concerned voxel of said set from a center of interest. Said set of voxels may comprise all voxels of the property map, or might be selected according to any known techniques, for instance by applying a mask to the acquired property map so as to select only a single type of tissue within the biological object, or only a part of the latter. At the end of step 120, each voxel of said set is thus associated to a distance d determined or measured for said voxel (i.e. if the set comprises for instance N voxels v₁, . . . , v_{N}, then to each voxel vi of the set, with i∈{1, . . . , N}, is associated a distance dᵢ). Preferably, said distance d is then stored, for each voxel of the set, in the memory 203 of the system 200 according to the invention. In the illustration of the invention presented in FIG. 3, the center of interest is preferentially a boundary of the lesion (i.e. the boundary between the lesion and the normal-appearing perilesional tissue), said distance d being the Euclidean distance between said boundary and the considered voxel. The center of interest can be the center of the lesion itself, or a border of the lesion (e.g., the closest border of the lesion) or a predefined spatial area in the biological object (e.g., a whole brain area such as the hippocampus or any other spatially defined region, e.g., periventricular region), or a specific anatomical landmark.

At step 130, the system 200, notably its control unit 202, is configured for fitting, for said set of voxels, a function f to the measured values V expressed in function of the determined distance d. This is better understood with the illustrations of FIGS. 3 and 4. Let's suppose that the property map 301 shown in FIG. 3 is a T1 map of a brain region comprising the lesion 302. The (intensity) value V of each voxel of the map is thus a T1 relaxation time that has been measured at a specific position within the biological object. The set of voxels is then for instance the voxels comprised in the normal-appearing perilesional region (see the perilesional tissue 303 in FIG. 3) surrounding the lesion 301. For each voxel of the set, the Euclidean distance d between the voxel and the border of the lesion has been measured by the control unit 202 from the position of the voxel and the position of the border. FIG. 4 shows then a graph representing the measured value V, i.e. the T1 relaxation time expressed in milliseconds in the present case, in function of the distance d expressed for instance in millimeter. This gives rise to a cloud of points that is then fitted by the function f according to V(d)=f(β₁, . . . , β_{N},d) wherein fitting parameters (β₁, . . . , β_{N}) are the unknown in the equation, and have thus to be determined. In the example of FIG. 4, f=β₀·e^{-β}^{ᵢ}^{d}+β₂, giving rise to

$$V ( d ) = T 1 ( d ) = {β}_{0} \cdot {e}^{- {β}_{1} d} + {β}_{2} \qquad Eq . 3$$

wherein β₀, β₁, and β₂ are the fitting parameters that need to be determined by the control unit 202. The mathematical model used for fitting V(d) can be based on any type of function (like the exponential function presented in association with FIG. 4), mathematical or geometrical transform or operation.

At step 140, the system 200, preferably its control unit 202, is configured for determining, from said fit, the values of each fitting parameter (β₁, . . . , β_{N}). For instance, according to the example provided in FIG. 4, the control unit 202 will be configured for determining the value of the fitting parameters β₀, β₁, and β₂.

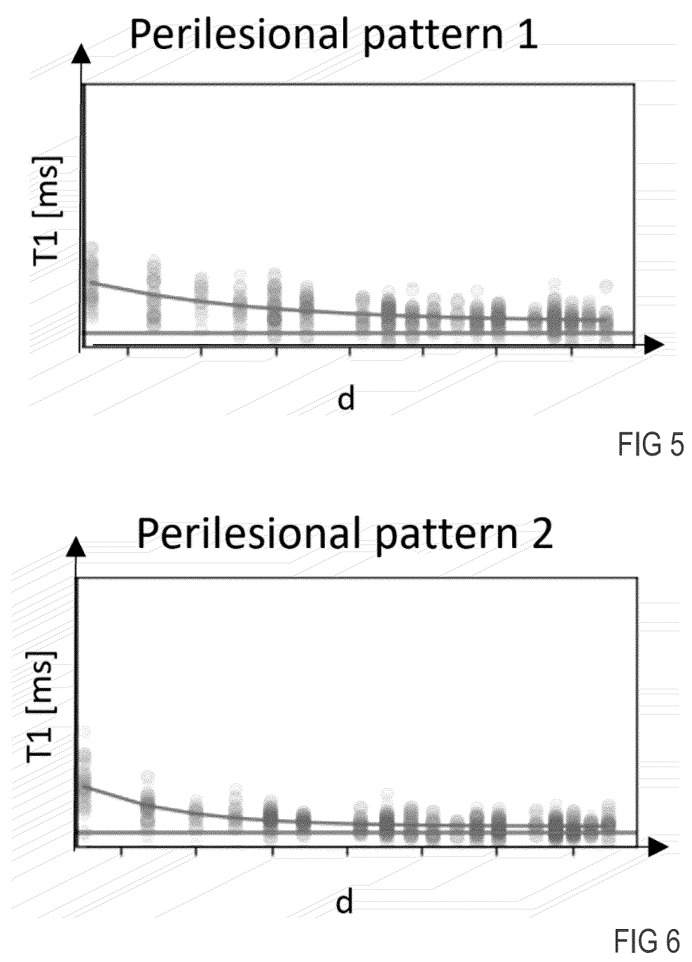

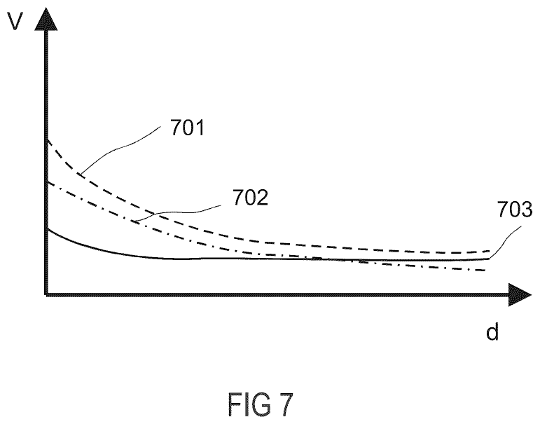

At step 150, the system 200, preferably its control unit 202, is configured for outputting the value of at least one of said fitting parameters. For instance, the control unit 202 may output the value of the fitting parameter β₁ and use the latter for a comparison with a reference value or for performing group-wise comparisons, for instance for identifying clusters of fitting parameters or cluster of fits (i.e., of fitting curves) that are alike (e.g., the closest to a mean), using for instance a k-means clustering method. Indeed, as shown in FIGS. 5 and 6, measured values of the relaxation time T1 as a function of the distance d might differ when considering a first lesion (FIG. 5) or a second lesion (FIG. 6). Therefore, each lesion will present a different perilesional pattern (namely a perilesional pattern 1 for the first lesion and a perilesional pattern 2 for the second lesion, as illustrated in the presented graphs) that can be characterized by the fitting parameters whose values (which are metrics) enable to compare the obtained pattern with a reference pattern (i.e. with reference values for said fitting parameters). Such comparison is better illustrated in FIG. 7, wherein, for a same type of tissue, different fitting curves 701, 702, 703 of the value Vin function of the distance d have been obtained each for a different biological object. The fitting parameters enable thus to spatially characterize the microstructural property of a tissue under examination. Notably, deviations of the value of a fitting parameter with respect to a reference value (e.g. obtained from a cohort of healthy people) might be used as additional tool for clinical analysis of tissue. Additionally, the present invention further proposes to use different fits (e.g. different fitting mathematical formulas for the function f) for reflecting different microstructural mechanisms, such as different lesion types in multiple sclerosis. In such a case, the present invention may enable to distinguish, for a same type of tissue, multiple classes of non-healthy tissue.

Finally, at step 150, the system 200, notably its control unit 202, is configured for displaying, via the display 204, said at least one fitting parameter, for instance in association with a reference value.

An advantage of the present invention is that it is based on property maps. It relies thus on absolute physical parameters of the tissue, resulting in better comparability between longitudinal scans of the same patients, between multi-site acquisitions or between different cohorts of subjects (e.g., healthy vs. pathological patients) in comparison to conventional “weighted” imaging. In particular, it can be used for providing fitting parameter values independent from hardware and other spurious effects, enabling notably the creation of “normative values” for the fitting parameters which might be used for defining a range of normal values seen in “normal” tissue and that will thus characterize a “normal” spatial distribution of a microstructural property under analysis when considering a tissue of interest. A fitting parameter value obtained then for an individual patient can be checked against such normative values in order to determine if the spatial distribution of the microstructural property obtained for said patient is within the known range of normative values or not. This may for instance help to better characterize a disease and improve diagnosis, providing for instance support to a radiologist or other medical doctor for a clinical decision. In particular, the extracted or outputted fitting parameter(s) might be automatically classified in a class of tissue by the control unit 202, wherein one or several classes of tissue (typically, several classes for a same type of tissue) are for instance predefined in the memory 203 of the system 200 in function of such range of normal values for the fitting parameter(s).

Finally, the previously described invention presents the following advantages with respect to the prior art:
It proposes a direct estimation of a spatial pattern measured for a microstructural property of a tissue;
It has an increased sensitivity with respect to prior techniques, wherein spatial patterns were estimated from an independent evaluation of different subregions. Indeed, since all voxels of the set are considered simultaneously to model the spatial pattern or distribution of the microstructural property, all information is persevered, achieving a higher sensitivity to the characterization of such pattern. This might allow, e.g., to distinguish more complex pathologies from each other;
It enables to determine spatial patterns which might be associated to specific (sub-) pathologies, lesion types or alike. Indeed, a spatial pattern (i.e. a fitting parameter) obtained for a biological object under analysis that is different from a normal pattern can then be categorized within a category of a set of categories, wherein each category defines a biologically different spatial pattern. For instance, a lesion can be associated to a category of lesions within a set of lesion categories that each represents a biologically different lesion pathology. The proposed method aggregates complex information contained in the property map and gives it a biological/medical meaning, facilitating the diagnostic assessment based on the fitting parameters.

To summarize, the present invention proposes to evaluate, within a tissue, a spatial distribution or pattern of a microstructural property of said tissue, wherein a mathematical model, i.e. said fitting function, is used for characterizing said spatial pattern from quantitative values acquired for said microstructural property, by associating each voxel of a property map acquired for said microstructural property with a continuous distance metric.

The following is a summary list of reference numerals and acronyms and the corresponding structure used in the above description of the invention:
MR magnetic resonance
MRI magnetic resonance imaging
qMRI quantitative magnetic resonance imaging
CT computed tomography
202 control unit
203 memory
204 display
120-150 method steps

List of citations appearing in the introductory text of the specification:
[1] Li, Xiaojuan, and Sharmila Majumdar. “Quantitative MRI of articular cartilage and its clinical applications.” Journal of Magnetic Resonance Imaging 38.5 (2013): 991-1008.
[2] Granziera, Cristina, et al. “Quantitative magnetic resonance imaging towards clinical application in multiple sclerosis.” Brain 144.5 (2021): 1296-1311.
[3] Vrenken, Hugo, et al., “Whole-Brain T1 Mapping in Multiple Sclerosis: Global Changes of Normal-appearing Gray and White Matter” Radiology (2006).
[4] Vaneckova, Manuela et al., “Periventricular gradient of T1 tissue alterations in multiple sclerosis” Neuroimage: Clinical (2022).
[5] Shi, Zhuowei, et al., “Microstructural alterations in different types of lesions and their perilesional white matter in relapsing-remitting multiple sclerosis based on diffusion kurtosis imaging”, Multiple Sclerosis and Related Disorders (2023).
[6]. Wittayer, Matthias, et al., “Exploring (peri-) lesional and structural connectivity tissue damage through T1/T2-weighted ratio in iron rim multiple sclerosis lesions”, Magnetic Resonance Imaging (2023).

1. A computer-implemented method for characterizing a spatial distribution of a tissue microstructural property from quantitative imaging data, the method comprising
acquiring, for a biological object and via a first interface, a property map for a tissue of the biological object, wherein the property map comprises voxels whose intensity represents a measured value V of the microstructural property for the tissue;
determining, for at least a set of the voxels, a distance d separating each voxel of the set from a center of interest so that each voxel of the set is associated with a measured value V and a determined distance d;
fitting, for the set of voxels, a function f to the measured values V expressed as a function of the determined distance d according to V(d)=f(β₁, . . . , β_{N},d) in order to determine a set of fitting parameters;
determining, from the fit, values of each fitting parameter; and
outputting a value of at least one of the fitting parameters.

2. The computer-implemented method according to claim 1, which comprises comparing the outputted value of the at least one fitting parameter to a reference value.

3. The computer implemented method of claim 2, which comprises automatically issuing a warning signal when a difference between the outputted value and the reference value is greater than a predefined threshold.

4. The computer-implemented method according to claim 1, which comprises automatically classifying the tissue in a class of tissue as a function of a value of at least one of the fitting parameters.

5. The computer-implemented method according to claim 1, wherein the function f further depends on a position \vec{r} of the voxel within a frame of reference according to V(\vec{r}, d)=f(β₁, . . . , β_{N}, \vec{r}, d).

6. A system for characterizing a spatial distribution of a tissue microstructural property from quantitative imaging data, the system comprising:
a first interface for receiving or acquiring a property map for a tissue of a biological object, wherein said property map comprises voxels whose intensity represents a measured value V of the microstructural property;
a memory for storing said property map;
a control unit with a processor, said control unit being configured for carrying out the method according to claim 1; and
a second interface, connected to said control unit, for outputting the value of at least one of said fitting parameters.

7. The system according to claim 6, wherein said control unit is further configured for comparing the outputted value to a reference value.

8. The system according to claim 7, wherein said control unit is further configured to automatically issue a warning signal when a difference between said outputted value and the reference value is greater than a predefined threshold.

9. The system according to claim 6, wherein said control unit is further configured to automatically classify the tissue in a class of tissue as a function of a value of at least one of the fitting parameters.

10. The system according to claim 6, wherein the function f further depends on a position \vec{r} of a voxel within a frame of reference according to V(\vec{r}, d)=f(β₁, . . . , β_{N}, \vec{r},d).

11. An imaging apparatus, comprising the system according to claim 6.

12. The imaging apparatus according to claim 11, wherein the imaging apparatus is a magnetic resonance imaging apparatus.
